(19) United States
(12) Patent Application Publication
(10) Pub. No.: US 2026/0101817 A1
(43) Pub. Date: Apr. 9, 2026

(54) SEMICONDUCTOR PACKAGE

(71) Applicant: SAMSUNG ELECTRONICS CO., LTD., Suwon-si (KR)

(72) Inventor: Keunyoung LEE, Suwon-si (KR)

(21) Appl. No.: 19/061,049

(22) Filed: Feb. 24, 2025

(30) Foreign Application Priority Data
Aug. 29, 2024 (KR) 10-2024-0116855

(51) Int. Cl. H01L 23/00; H01L 25/16; H10B 80/00; H10D 80/30

(52) U.S. Cl. CPC H10W 90/00; H10B 80/00; H10D 80/30; H10W 72/015; H10W 72/07552; H10W 72/07553; H10W 72/527; H10W 72/531; H10W 72/537; H10W 72/5445; H10W 72/552; H10W 72/5522; H10W 72/5525; H10W 72/884; H10W 72/9445; H10W 72/952; H10W 90/24; H10W 90/724; H10W 90/732; H10W 90/734; H10W 90/752; H10W 90/754

(57) ABSTRACT

A semiconductor package includes a substrate, a first semiconductor die disposed on the substrate, a second semiconductor die stacked on the first die and offset from it in a first direction and a second direction that are perpendicular to each other, and a third semiconductor die stacked on the first and second dies and offset from them in the first direction. The first semiconductor die includes a first pad and a second pad, arranged successively in the second direction. The second semiconductor die includes a third pad and a fourth pad, and the third semiconductor die includes a fifth pad and a sixth pad, each arranged successively in the second direction. A first conductive pattern connects the first and fifth pads, while a second conductive pattern connects the second, fourth, and sixth pads. The first and second conductive patterns are spaced apart from the third pad.

### CROSS-REFERENCE TO RELATED APPLICATIONS

This application claims priority under 35 U.S.C. § 119 to Korean Patent Application No. 10-2024-0116855, filed on Aug. 29, 2024, the disclosure of which is hereby incorporated by reference in its entirety.

### TECHNICAL FIELD

Embodiments of the present disclosure relate to a semiconductor package.

### DISCUSSION OF RELATED ART

A semiconductor package may be configured to facilitate the use of an integrated circuit chip as a component in an electronic product. In general, the semiconductor package may include a printed circuit board (PCB) and a semiconductor chip, which is mounted on the PCB and is electrically connected to the PCB using bonding wires or bumps. As the semiconductor industry advances, research is being conducted to improve the reliability of semiconductor packages.

### SUMMARY

An embodiment of the present disclosure provides a semiconductor package with high signal transmission efficiency and high reliability.

According to an embodiment of the present disclosure, a semiconductor package includes a substrate, a first semiconductor die disposed on the substrate, a second semiconductor die disposed on the first semiconductor die, a third semiconductor die disposed on the second semiconductor die, a first conductive pattern, and a second conductive pattern. The second semiconductor die is stacked on the first semiconductor die and is offset from the first semiconductor die in a first direction and a second direction, which are perpendicular to each other. The third semiconductor die is stacked on the first and second semiconductor dies and is offset from the first and second semiconductor dies in the first direction. The first semiconductor die includes a first pad and a second pad, which are successively arranged in the second direction. The second semiconductor die includes a third pad and a fourth pad, which are successively arranged in the second direction. The third semiconductor die includes a fifth pad and a sixth pad, which are successively arranged in the second direction. The first conductive pattern connects the first and fifth pads, and the second conductive pattern connects the second, fourth, and sixth pads. The first and second conductive patterns are spaced apart from the third pad.

According to an embodiment of the present disclosure, a semiconductor package includes a substrate, a first semiconductor die disposed on the substrate, a second semiconductor die disposed on the first semiconductor die, a first conductive pattern, and a second conductive pattern. The second semiconductor die is stacked on the first semiconductor die and is offset from the first semiconductor die in a first direction and a second direction, which are perpendicular to each other. The substrate includes a first substrate pad and a second substrate pad, which are spaced apart from each other in the second direction. The first semiconductor die includes a first insulating layer and a first pad exposed from the first insulating layer, and the second semiconductor die includes a second pad. The first conductive pattern is disposed between the first substrate pad and the first pad, and the second conductive pattern is disposed between the second substrate pad and the second pad. The second conductive pattern is spaced apart from the first conductive pattern, and the second conductive pattern is in contact with a top surface of the first insulating layer.

According to an embodiment of the present disclosure, a semiconductor package includes a substrate, a semiconductor die stack disposed on the substrate, a mold layer covering a top surface and a side surface of the semiconductor die stack, a first conductive pattern, a second conductive pattern, and a third conductive pattern. The semiconductor die stack includes a first semiconductor die disposed on the substrate, a second semiconductor die disposed on the first semiconductor die, a third semiconductor die disposed on the second semiconductor die, and a fourth semiconductor die disposed on the third semiconductor die. The second and fourth semiconductor dies are offset from the first semiconductor die in a first direction and a second direction, and the third semiconductor die is offset from the first semiconductor die in the first direction and is disposed at a same position in the second direction. The fourth semiconductor die is offset from the second semiconductor die in the first direction and is disposed at a same position in the second direction. The first semiconductor die includes a first signal pad and a first voltage pad, which are spaced apart from each other in the second direction, and the second semiconductor die includes a second signal pad and a second voltage pad, which are spaced apart from each other in the second direction. The third semiconductor die includes a third signal pad and a third voltage pad, which are spaced apart from each other in the second direction, and the fourth semiconductor die includes a fourth signal pad and a fourth voltage pad, which are spaced apart from each other in the second direction. The first conductive pattern connects the first and third signal pads, the second conductive pattern connects the second and fourth signal pads, and the third conductive pattern connects the first, second, third, and fourth voltage pads.

According to an embodiment of the present disclosure, a method of forming a semiconductor package includes forming a semiconductor die stack by stacking a plurality of semiconductor dies on a substrate. The semiconductor dies are sequentially stacked and offset from each other. The method further includes forming an insulating pattern by coating side surfaces of the semiconductor dies with a polymer insulating material, and forming a conductive pattern by ejecting a conductive material onto top and side surfaces of the semiconductor dies using a nozzle and sintering the conductive material.

In an embodiment, the conductive material is a silver nanoparticle ink, and the sintering combines silver particles of the silver nanoparticle ink to form the conductive pattern.

In an embodiment, the conductive pattern is formed using an inkjet printing technique.

### BRIEF DESCRIPTION OF THE DRAWINGS

The above and other features of the present disclosure will become more apparent by describing in detail embodiments thereof with reference to the accompanying drawings.

FIG. 1 is a plan view illustrating a semiconductor package according to an embodiment of the present disclosure.

FIG. 2 is a perspective view of FIG. 1.

FIG. 3 is a cross-sectional view taken along line I-I′ of FIG. 1.

FIG. 4 is an enlarged view illustrating a portion ‘EV1’ of FIG. 1.

FIG. 5 is an enlarged view illustrating a portion ‘EV2’ of FIG. 3.

FIG. 6 is a cross-sectional view illustrating a semiconductor package according to an embodiment of the present disclosure.

FIG. 7 is a plan view illustrating a semiconductor package according to an embodiment of the present disclosure.

FIG. 8 is a perspective view of FIG. 7.

FIG. 9 is a cross-sectional view taken along line I-I′ of FIG. 7.

FIG. 10 is an enlarged view illustrating a portion ‘EV3’ of FIG. 9.

FIG. 11 is a plan view illustrating a semiconductor package according to an embodiment of the present disclosure.

FIG. 12 is a perspective view of FIG. 11.

FIG. 13 is an enlarged view illustrating a portion ‘EV4’ of FIG. 11.

FIG. 14 is a cross-sectional view illustrating a method of fabricating a semiconductor package according to an embodiment of the present disclosure.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ±30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

Embodiments of the present disclosure provide a semiconductor package designed to improve signal transmission efficiency, reliability, and manufacturability. The package may include a stack of semiconductor dies arranged in a staggered configuration, which may reduce space requirements and overall package height. Instead of traditional bonding wires, conductive patterns may be utilized to establish connections between the dies. These conductive patterns may make direct contact with the top and side surfaces of each die and have a shorter length compared to bonding wires, thereby reducing the overall electrical path. The elimination of the wire bonding process may further reduce the required package height and simplify manufacturing.

The conductive patterns may be fabricated using advanced inkjet printing techniques, which may improve precision and scalability. A common conductive pattern may be incorporated to effectively manage voltage across the dies, which may improve stability and reliability. Additionally, semiconductor dies with different signal channels may be efficiently stacked in a single configuration, which may improve space utilization and reduce the package's area. Insulating patterns may be included to protect and stabilize the conductive patterns and maintain electrical integrity. Accordingly, embodiments of the present disclosure may improve the performance, reliability, and efficiency of a semiconductor package.

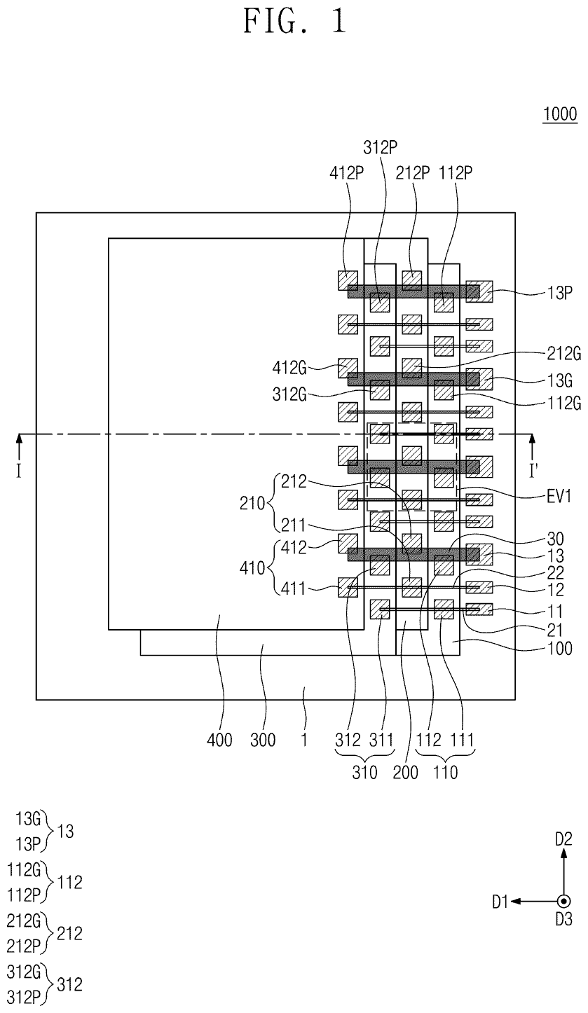

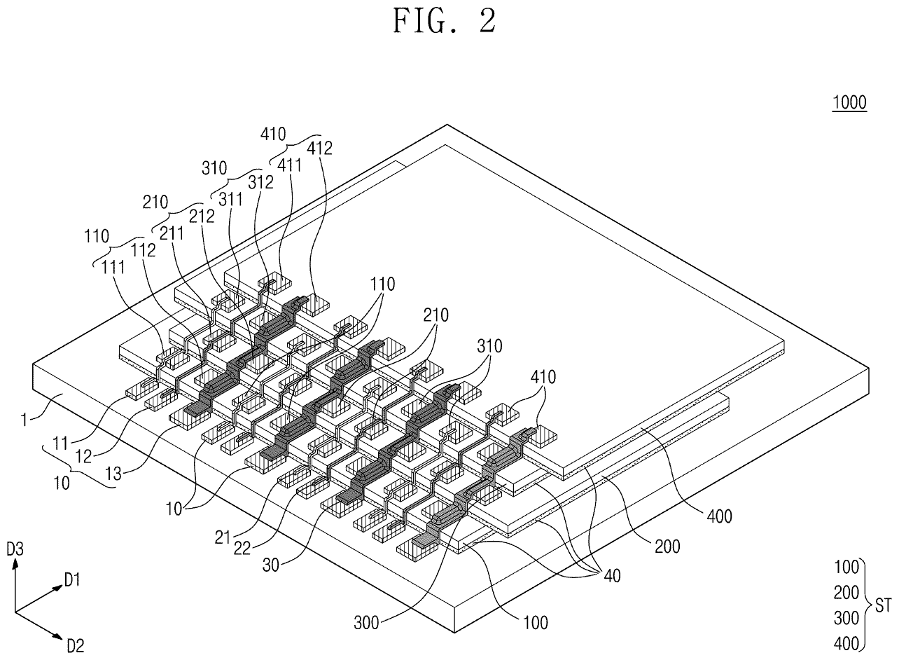

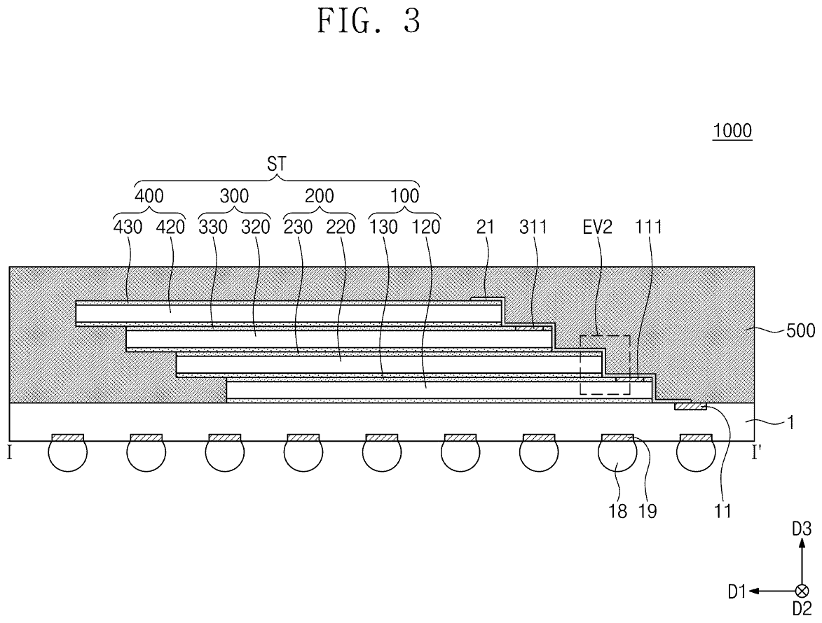

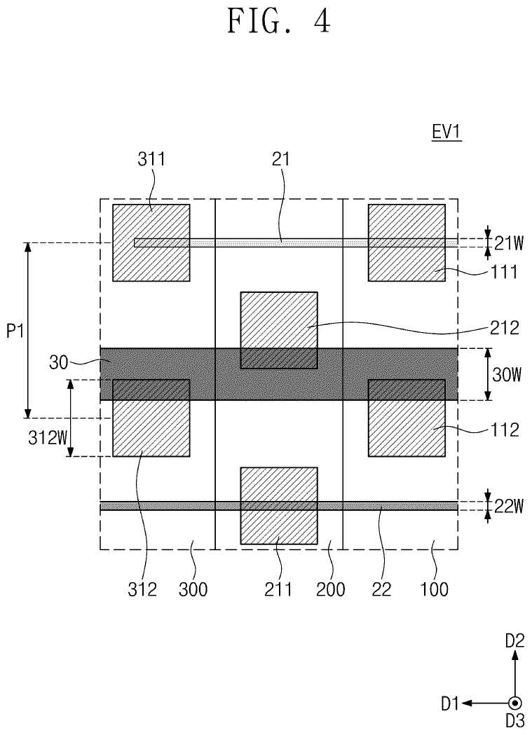

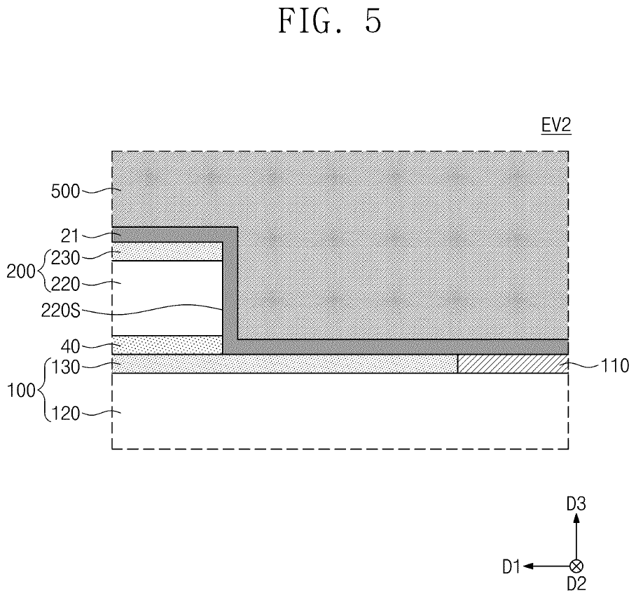

FIG. 1 is a plan view illustrating a semiconductor package according to an embodiment of the present disclosure. FIG. 2 is a perspective view of FIG. 1. FIG. 3 is a cross-sectional view taken along line I-I′ of FIG. 1. FIG. 4 is an enlarged view illustrating a portion ‘EV1’ of FIG. 1. FIG. 5 is an enlarged view illustrating a portion ‘EV2’ of FIG. 3. To provide a better understanding of the present disclosure, some elements of the semiconductor package may be omitted from FIGS. 1 and 2.

Referring to FIGS. 1, 2, and 3, a semiconductor package 1000 may include a substrate 1, a semiconductor die stack ST, a mold layer 500 and an outer connection terminal 18.

The substrate 1 may be, for example, a printed circuit board (PCB). In an embodiment, the substrate 1 may be a redistribution substrate. The substrate 1 may have, for example, a rectangular shape, when viewed in a plan view. In the present specification, a first direction D1 and a second direction D2 may be directions that are parallel to side edges of the substrate 1. The first and second directions D1 and D2 may be orthogonal to each other. A third direction D3 may be a direction perpendicular to a top surface of the substrate 1. In the present specification, the first direction D1, the second direction D2, and the third direction D3 may be directions of X, Y, and Z axes.

The substrate 1 may include a plurality of substrate pads 10. The substrate pads 10 may be arranged in the second direction D2. The substrate pads 10 may include a first substrate pad 11, a second substrate pad 12, and a third substrate pad 13, which are arranged in the second direction D2. Although the first, second, and third substrate pads 11, 12, and 13 are illustrated to be sequentially arranged in the second direction D2, the arrangement may be variously changed according to embodiments. The first and second substrate pads 11 and 12 may be signal pads, respectively. The third substrate pad 13 may be a ground pad 13G or a power pad 13P. For example, the first substrate pad 11, the second substrate pad 12, the ground pad 13G, the first substrate pad 11, the second substrate pad 12, and the power pad 13P may be sequentially arranged in the second direction D2. In an embodiment, the ground pads 13G and the power pads 13P may be alternatively arranged. In the present specification, the signal pad may be used to transmit data or control signals. The ground pad may be maintained to 0 V and may be used to provide a common reference potential to a circuit. The power pad may be used to apply a power supply voltage to the circuit of the semiconductor die. The size of the third substrate pad 13 may be larger than the size of the first substrate pad 11 and the size of the second substrate pad 12. For example, the width of the third substrate pad 13 in the second direction D2 may be greater than the width of the first substrate pad 11 in the second direction D2 and the width of the second substrate pad 12 in the second direction D2.

The semiconductor die stack ST may include a first semiconductor die 100, a second semiconductor die 200, a third semiconductor die 300, a fourth semiconductor die 400, a first conductive pattern 21, a second conductive pattern 22, and a third conductive pattern 30. In the present specification, the third conductive pattern 30 may be referred to as a common conductive pattern 30.

The first to fourth semiconductor dies 100 to 400 may include an integrated memory circuit. For example, the first to fourth semiconductor dies 100 to 400 may be NAND FLASH memory chips. The first and third semiconductor dies 100 and 300 may be configured to have the same signal channel. The second and fourth semiconductor dies 200 and 400 may be configured to have the same signal channel. The signal channel in the first and third semiconductor dies 100 and 300 may be different from the signal channel in the second and fourth semiconductor dies 200 and 400. For example, the first and third semiconductor dies 100 and 300 may have a signal channel 0, and the second and fourth semiconductor dies 200 and 400 may have a signal channel 1. The signal channel 0 and the signal channel 1 may mean signal paths, which are used for a data transmission operation and a data management operation in the NAND FLASH memory chip. The signal channel 0 and the signal channel 1 may serve as a logical signal channel and a physical signal channel. The logical signal channel may be a logical path, which is used to manage data in the NAND memory chip. The physical signal channel may be a physical communication path, which is actually used to transmit data. The signal channel 0 and the signal channel 1 may be operated in an independent manner, and in this case, the performance of the semiconductor die stack ST may be improved through a parallel processing technology.

For example, according to embodiments, the first, second, third, and fourth semiconductor dies 100, 200, 300, and 400 may each incorporate an integrated memory circuit. For example, these semiconductor dies can be configured as NAND FLASH memory chips. Among them, the first and third semiconductor dies 100 and 300 may share the same signal channel, while the second and fourth semiconductor dies 200 and 400 may share a different signal channel. The signal channel assigned to the first and third semiconductor dies 100 and 300 may be distinct from the signal channel assigned to the second and fourth semiconductor dies 200 and 400. For example, the first and third semiconductor dies 100 and 300 may utilize signal channel 0, whereas the second and fourth semiconductor dies 200 and 400 may utilize signal channel 1. Signal channels 0 and 1 represent pathways used for specific operations within the NAND FLASH memory chips. These pathways may support both data transmission and data management functionalities. Signal channel 0 and signal channel 1 may each function as both a logical signal channel and a physical signal channel. The logical signal channel refers to the logical representation used for managing data within the memory chip, while the physical signal channel corresponds to the tangible communication pathway that facilitates actual data transmission. Signal channel 0 and signal channel 1 can operate independently of one another. This independence may enable the semiconductor die stack ST to utilize parallel processing technology, which may improve its overall performance.

The first, second, third, and fourth semiconductor dies 100, 200, 300, and 400 may be stacked in a staggered manner to form a stepwise shape. The second semiconductor die 200 may be disposed on the first semiconductor die 100 to be offset from the first semiconductor die 100 in the first and second directions D1 and D2. As will be described below, the first to fourth semiconductor dies 100, 200, 300, and 400 may include pads, and the pads may be arranged in the second direction D2 at a first pitch. For example, the pads may be successively and repeatedly arranged in the second direction D2 at a first pitch. The length by which the second semiconductor die 200 is offset from the first semiconductor die 100 in the second direction D2 may be less than or about equal to half of the first pitch. The third semiconductor die 300 may be disposed on the second semiconductor die 200 to be offset from the second semiconductor die 200 in the first and second directions D1 and D2. The length by which the third semiconductor die 300 is offset from the second semiconductor die 200 in the second direction D2 may be less than or about equal to half of the first pitch. The third semiconductor die 300 may be offset from the first semiconductor die 100 in the first direction D1 and may be placed at substantially the same position in the second direction D2. That is, the third semiconductor die 300 may be stacked on the first semiconductor die 100 in such a way that it is offset from the first semiconductor die 100 in the first direction D1, with no displacement in in the second direction D2. The fourth semiconductor die 400 may be disposed on the third semiconductor die 300 to be offset from the first and third semiconductor dies 100 and 300 in the first and second directions D1 and D2. The length by which the fourth semiconductor die 400 is offset from the first and third semiconductor dies 100 and 300 in the second direction D2 may be less than or about equal to half of the first pitch. The fourth semiconductor die 400 may be offset from the second semiconductor die 200 in the first direction D1 and may be placed at substantially the same position as the second semiconductor die 200 in the second direction D2. That is, the fourth semiconductor die 400 may be stacked on the second semiconductor die 200 in such a way that it is offset from the second semiconductor die 200 in the first direction D1, with no displacement in the second direction D2.

For example, according to embodiments, the first, second, third, and fourth semiconductor dies 100, 200, 300, and 400 may be stacked in a staggered arrangement, creating a stepwise configuration. The second semiconductor die 200 may be positioned on the first semiconductor die 100 and may be offset relative to the first semiconductor die 100 along both the first direction D1 and the second direction D2. As described further below, each of the first to fourth semiconductor dies 100, 200, 300, and 400 may include pads arranged along the second direction D2 with a spacing defined at a first pitch. The degree of offset between the second semiconductor die 200 and the first semiconductor die 100 in the second direction D2 may be less than or about equal to half of the first pitch.

The third semiconductor die 300 may be stacked on the second semiconductor die 200 and may be offset from the second semiconductor die 200 in both the first direction D1 and the second direction D2. Similarly, the offset between the third semiconductor die 300 and the second semiconductor die 200 in the second direction D2 may also be less than or about equal to half of the first pitch. In the first direction D1, the third semiconductor die 300 may be offset from the first semiconductor die 100, while in the second direction D2, the third semiconductor die 300 may be positioned substantially in the same alignment as the first semiconductor die 100. For example, the third semiconductor die 300 may be stacked on the first semiconductor die 100 such that the third semiconductor die 300 is displaced in the first direction D1 but not in the second direction D2.

The fourth semiconductor die 400 may be positioned on the third semiconductor die 300 and may be offset from the first and third semiconductor dies 100 and 300 along both the first direction D1 and the second direction D2. The offset of the fourth semiconductor die 400 relative to the first and third semiconductor dies 100 and 300 in the second direction D2 may also be less than or about equal to half of the first pitch. In the first direction D1, the fourth semiconductor die 400 may be displaced from the second semiconductor die 200, but in the second direction D2, the fourth semiconductor die 400 may align substantially with the second semiconductor die 200. Thus, the fourth semiconductor die 400 may be stacked on the second semiconductor die 200 such that the fourth semiconductor die 400 may be offset in the first direction D1 but remain aligned in the second direction D2.

As shown in FIGS. 2 and 3, an adhesive layer 40 may be interposed between the first semiconductor die 100 and the second semiconductor die 200, between the second semiconductor die 200 and the third semiconductor die 300, and between the third semiconductor die 300 and the fourth semiconductor die 400. The adhesive layer 40 may be, for example, a die attach film (DAF). The adhesive layer 40 may include an adhesive polymer material. The adhesive layer 40 may have an area that is about equal to or larger than an area of a bottom surface of each of the semiconductor dies 100, 200, 300, and 400.

The first semiconductor die 100 may include first column pads 110, which are arranged in the second direction D2. The first column pads 110 may include a first signal pad 111 and a first voltage pad 112. The first voltage pad 112 may be a first ground pad 112G or a first power pad 112P. For example, the first ground pads 112G and the first power pads 112P may be alternately disposed in the second direction D2. The first signal pads 111 and the first voltage pads 112 may be spaced apart from each other in the second direction D2 by the first pitch. The second semiconductor die 200 may include second column pads 210, which are arranged in the second direction D2. The second column pads 210 may include a second signal pad 211 and a second voltage pad 212. The second voltage pad 212 may be a second ground pad 212G or a second power pad 212P. For example, the second ground pads 212G and the second power pads 212P may be alternately disposed in the second direction D2. The second signal pads 211 and the second voltage pads 212 may be spaced apart from each other in the second direction D2 by the first pitch. The third semiconductor die 300 may include third column pads 310, which are arranged in the second direction D2. The third column pads 310 may include a third signal pad 311 and a third voltage pad 312. The third voltage pad 312 may be a third ground pad 312G or a third power pad 312P. For example, the third ground pads 312G and the third power pads 312P may be alternately disposed in the second direction D2. The third signal pads 311 and the third voltage pads 312 may be spaced apart from each other in the second direction D2 by the first pitch. The fourth semiconductor die 400 may include fourth column pads 410, which are arranged in the second direction D2. The fourth column pads 410 may include a fourth signal pad 411 and a fourth voltage pad 412. The fourth voltage pad 412 may be a fourth ground pad 412G or a fourth power pad 412P. For example, the fourth ground pads 412G and the fourth power pads 412P may be alternately disposed in the second direction D2. The fourth signal pads 411 and the fourth voltage pads 412 may be spaced apart from each other in the second direction D2 by the first pitch.

When viewed in the plan view of FIG. 1, the first substrate pad 11, the first signal pad 111, and the third signal pad 311 may be aligned with each other in the first direction D1. The second substrate pad 12, the second signal pad 211, and the fourth signal pad 411 may be aligned with each other in the first direction D1. The third substrate pad 13, along with the first voltage pad 112, the second voltage pad 212, the third voltage pad 312, and the fourth voltage pad 412, may be aligned with each other in the first direction D1. The first signal pad 111, the second signal pad 211, the third signal pad 311, and the fourth signal pad 411 may be arranged to form a zigzag shape extending along the first direction D1. The first voltage pad 112, the second voltage pad 212, the third voltage pad 312, and the fourth voltage pad 412 may be arranged to form a zigzag shape extending along the first direction D1. For example, the arrangement of the first, second, third, and fourth signal pads 111, 211, 311, and 411 may form a zigzag pattern extending along the first direction D1, and similarly, the first, second, third, and fourth voltage pads 112, 212, 312, and 412 may also be configured in a zigzag pattern extending along the first direction D1.

Each of the first to third substrate pads 11, 12, and 13, the first to fourth signal pads 111, 211, 311, and 411, and the first to fourth voltage pads 112, 212, 312, and 412 may be formed of or include at least one of metallic materials (e.g., gold, copper, silver, aluminum, nickel, and palladium).

Referring to FIGS. 1 and 2, the first conductive pattern 21 may be disposed on the first substrate pad 11, the first signal pad 111, and the third signal pad 311 to connect the first substrate pad 11, the first signal pad 111, and the third signal pad 311 to each other. The second conductive pattern 22 may be disposed on the second substrate pad 12, the second signal pad 211, and the fourth signal pad 411 to connect the second substrate pad 12, the second signal pad 211, and the fourth signal pad 411 to each other. The third conductive pattern 30 may be disposed on the third substrate pad 13, the first voltage pad 112, the second voltage pad 212, the third voltage pad 312, and the fourth voltage pad 412 to connect the third substrate pad 13, the first voltage pad 112, the second voltage pad 212, the third voltage pad 312, and the fourth voltage pad 412 to each other. That is, the third conductive pattern 30 may be commonly connected to the substrate 1 and the first, second, third, and fourth semiconductor dies 100, 200, 300, and 400. When viewed in a plan view, each of the first, second, and third conductive patterns 21, 22, and 30 may be a straight-line pattern extended in the first direction D1. For example, when viewed in a plan view, the first, second, and third conductive patterns 21, 22, and 30 may each extend as straight-line patterns along the first direction D1 while being spaced apart from one another along the second direction D2. The first, second, and third conductive patterns 21, 22, and 30 may be spaced apart from each other in the second direction D2. For example, the second conductive pattern 22 and the third conductive pattern 30 may be interposed between two first conductive patterns 21, which are disposed adjacent to each other in the second direction D2.

Referring to FIGS. 1 and 4, the first conductive pattern 21 may have a first width 21W in the second direction D2, the second conductive pattern 22 may have a second width 22W in the second direction D2, and the third conductive pattern 30 may have a third width 30W in the second direction D2. The third width 30W may be greater than the first width 21W and the second width 22W. The voltage pad (e.g., 312) may be spaced apart from other pads (e.g., 311), which are disposed adjacent thereto in the second direction D2, at a first pitch P1. The third width 30W may be smaller than the first pitch P1. The third width 30W may be greater than about half of the first pitch P1, minus the width (e.g., 312W) of the voltage pad (e.g., 312), in the second direction D2. Under the given condition, the third conductive pattern 30 having the third width 30W may be in contact with all of the first voltage pad 112, the second voltage pad 212, the third voltage pad 312, and the fourth voltage pad 412 but may not be in contact with other signal pads 111, 211, 311, and 411. Since the third conductive pattern 30 applied with a voltage has the third width 30W greater than a specific width, the third conductive pattern 30 may have a reduced electric resistance and may be used to more stably deliver the voltage. For example, the third width 30W may range from about 50 μm to about 100 μm.

For example, according to embodiments, referring to FIGS. 1 and 4, the first conductive pattern 21 may have a width designated as 21W in the second direction D2, the second conductive pattern 22 may have a width designated as 22W in the second direction D2, and the third conductive pattern 30 may have a width designated as 30W in the second direction (D2). Among these widths, the third width 30W may be greater than both the first width 21W and the second width 22W. The voltage pad (e.g., 312) may be spaced apart from adjacent pads (e.g., 311) in the second direction D2 at a first pitch P1. The third width 30W may be smaller than the first pitch P1 but greater than about half of the first pitch P1 minus the width (e.g., 312W) of the voltage pad (e.g., 312). Under these conditions, the third conductive pattern 30, with its width of 30W, may be in contact with all of the voltage pads, including the first voltage pad 112, the second voltage pad 212, the third voltage pad 312, and the fourth voltage pad 412, while remaining out of contact with the signal pads 111, 211, 311, and 411. With its width exceeding a specific threshold, the third conductive pattern 30 may exhibit reduced electrical resistance, enabling more stable voltage delivery. For example, the third width 30W may range from about 50 μm to 100 μm.

Signals, which are included in the signal channel 0, may be transmitted through a first conductive pattern 20 connecting the first substrate pad 11, the first signal pad 111, and a third signal pad 31. Signals, which are included in the signal channel 1, may be transmitted through the first conductive pattern 20 connecting the second substrate pad 12, the second signal pad 211, and the fourth signal pad 411. For example, signals associated with signal channel 0 may be transmitted via the first conductive pattern 20, which connects the first substrate pad 11, the first signal pad 111, and the third signal pad 311, and similarly, signals associated with signal channel 1 may be transmitted via the first conductive pattern 20, which connects the second substrate pad 12, the second signal pad 211, and the fourth signal pad 411. A ground voltage may be transmitted through the third conductive pattern 30 connecting the ground pad 13G of the substrate 1, the first ground pad 112G, the second ground pad 212G, the third ground pad 312G, and the fourth ground pad 412G. A power voltage may be transmitted through the third conductive pattern 30 connecting the power pad 13P of the substrate, the first power pad 112P, the second power pad 212P, the third power pad 312P, and the fourth power pad 412P.

The first conductive pattern 21, the second conductive pattern 22, and a third conductive pattern 33 may be formed of or include at least one of metallic materials (e.g., silver, copper, gold, nickel, and palladium). The first conductive pattern 21, the second conductive pattern 22, and the third conductive pattern 33 may be, for example, a silver-containing metal pattern.

Referring to FIGS. 2, 3, and 5, the first conductive pattern 21 may also be in contact with top and side surfaces of the third semiconductor die 300, top and side surfaces of the second semiconductor die 200, top and side surfaces of the first semiconductor die 100, and the top surface of the substrate 1. The second conductive pattern 22 and the third conductive pattern 30 may also be in contact with top and side surfaces of the fourth semiconductor die 400, the top and side surfaces of the third semiconductor die 300, the top and side surfaces of the second semiconductor die 200, the top and side surfaces of the first semiconductor die 100. For example, the first semiconductor die 100 may further include a first semiconductor substrate 120 provided with an integrated circuit, a first insulating layer 130, and interconnection lines. The first signal pad 111 and the first voltage pad 112 may be exposed from the first insulating layer 130. According to embodiments, the interconnection lines may electrically connect the integrated circuit to the first signal pad 111 and the first voltage pad 112. The first insulating layer 130 may be formed of or include at least one of inorganic insulating materials (e.g., silicon oxide, silicon nitride, and silicon oxynitride). The interconnection lines may be formed of or include at least one of metallic materials (e.g., copper, aluminum, gold, and silver). The second semiconductor die 200 may include a second semiconductor substrate 220, a second insulating layer 230, and interconnection lines. The third semiconductor die 300 may include a third semiconductor substrate 320, a third insulating layer 330, and interconnection lines. The fourth semiconductor die 400 may include a fourth semiconductor substrate 420, a fourth insulating layer 430, and interconnection lines. The semiconductor substrates 220, 320, and 420, the insulating layers 230, 330, and 430, and the interconnection lines of the second, third, and fourth semiconductor dies 200, 300, and 400 may have substantially the same function as the first semiconductor substrate 120, the first insulating layer 130, and the interconnection line of the first semiconductor die 100 described above and may be formed of or include the same or similar material.

Referring to FIG. 5, the first conductive pattern 21 may be in contact with the top and side surfaces of the second insulating layer 230, a side surface 220S of the second semiconductor substrate 220, the side surface of the adhesive layer 40, and the top surface of the first insulating layer 130. The sum of the height of the second semiconductor die 200 and the thickness of the adhesive layer 40 may be smaller than a distance from the side surface of the second semiconductor die 200 to the first column pad 110.

Referring back to FIG. 3, the mold layer 500 may cover the top surface of the substrate 1, the semiconductor die stack ST, and the conductive patterns 21, 22, 30. The mold layer 500 may include, for example, an epoxy molding compound (EMC).

The substrate 1 may include lower pads 19 disposed on a bottom surface thereof. The lower pads 19 may be electrically connected to the first, second, and third substrate pads 11, 12, and 13 through the interconnection lines in the substrate 1. The outer connection terminals 18 may be disposed on the lower pads 19, respectively. The outer connection terminals 18 may be at least one of, for example, solder balls, solder bumps, and pillars. The outer connection terminals 18 may be formed of or include at least one of metallic materials (e.g., silver and tin). The present specification illustrates an example in which four semiconductor dies are stacked. However, embodiments are not limited thereto. For example, according to embodiments, two, eight, or twelve semiconductor dies may be stacked in the aforementioned manner.

In a semiconductor package according to an embodiment of the present disclosure, a conductive pattern, not a bonding wire, may be used to connect first to fourth semiconductor dies. The conductive pattern may be in direct contact with top and side surfaces of the semiconductor die and may have a length shorter than the bonding wire, and thus, an overall length of the electric path may be reduced. In addition, since a space for a wire bonding process is not required, an overall height of the semiconductor package may also be reduced.

For example, in a semiconductor package according to an embodiment of the present disclosure, a conductive pattern is utilized instead of a traditional bonding wire to establish connections between the first to fourth semiconductor dies. The conductive pattern may be designed to make direct contact with the top and side surfaces of each semiconductor die. Since the length of the conductive pattern is shorter compared to that of a bonding wire, the overall length of the electrical path may be reduced. Further, because the wire bonding process is eliminated, the space typically required for this process is no longer needed, allowing for a reduction in the overall height of the semiconductor package.

In a semiconductor package according to an embodiment of the present disclosure, semiconductor dies with different signal channels may be provided. The semiconductor dies may be stacked to form a zigzag shape extending along a first direction, and a straight-line conductive pattern may be used to connect the semiconductor dies having the same signal channel in the first direction. By stacking the semiconductor dies with different signal channels in a single semiconductor die stack, the area of the semiconductor package may be reduced. If the semiconductor dies with different signal channels are stacked side-by-side with an offset in the first direction, connecting the semiconductor dies with a straight-line conductive pattern is undesirable, because different signal channels are connected to the same conductive pattern. To utilize the conductive pattern, the semiconductor dies may be provided to form two different die stacks, each of which includes dies of only the signal channel 0 or 1, and in this case, the required area of the semiconductor package may be increased.

In a semiconductor package according to an embodiment of the present disclosure, a common conductive pattern (e.g., the third conductive pattern) may be provided to apply the same voltage to the semiconductor dies with different signal channels. Since a plurality of semiconductor dies are connected to the common conductive pattern, voltage management may be efficiently executed. In addition, the common conductive pattern may be provided to have a thickness greater than a specific thickness, and in this case, effective voltage transmission may be achieved.

For example, in a semiconductor package according to an embodiment of the present disclosure, semiconductor dies with different signal channels may be included. These semiconductor dies can be arranged in a zigzag pattern extending along a first direction, enabling the use of a straight-line conductive pattern to connect dies sharing the same signal channel within that direction. By integrating semiconductor dies with different signal channels into a single stacked configuration, the overall area of the semiconductor package can be reduced. In contrast, if semiconductor dies with different signal channels are arranged side-by-side with an offset in the first direction, using a straight-line conductive pattern may become impractical because it could unintentionally connect dies with different signal channels to the same conductive pattern. To address this, separate die stacks may be formed, with each stack including dies dedicated to only one signal channel (e.g., channel 0 or channel 1). However, this approach may increase the area required for the semiconductor package.

In an embodiment of the present disclosure, a common conductive pattern (e.g., the third conductive pattern) may be provided to supply the same voltage across semiconductor dies with different signal channels. This common conductive pattern may facilitate efficient voltage management by connecting multiple semiconductor dies. Further, the common conductive pattern may be designed with a thickness greater than a specified minimum value, allowing for effective and reliable voltage transmission.

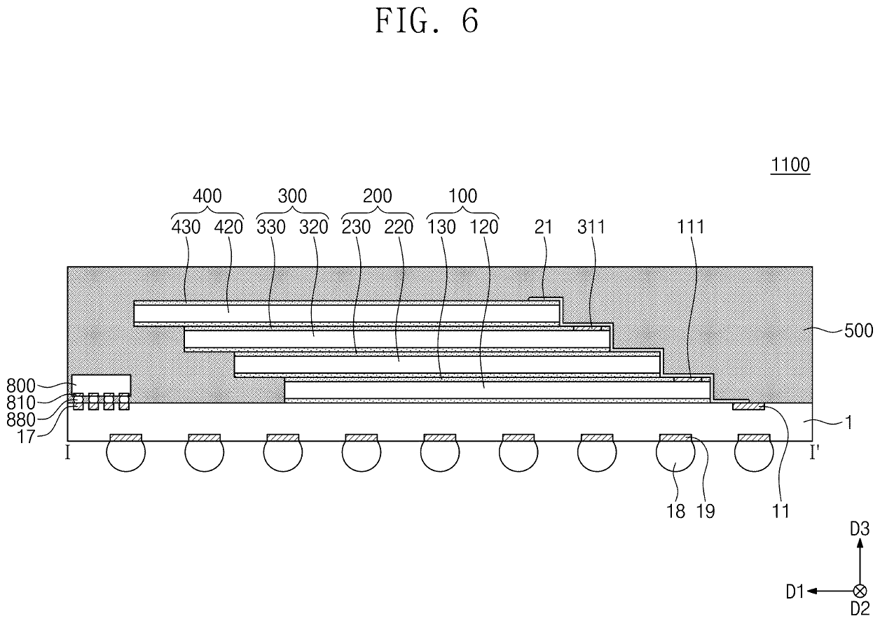

FIG. 6 is a cross-sectional view illustrating a semiconductor package according to an embodiment of the present disclosure. Referring to FIG. 6, a semiconductor package 1100 according to an embodiment of the present disclosure may further include an electronic device 800. The electronic device 800 may be disposed on the substrate 1. Although one electronic device 800 is illustrated in FIG. 6, the number of the electronic device 800 may be increased. The electronic device 800 may include a connection pad 810. The substrate 1 may include an upper pad 17 disposed on the top surface thereof. A connection terminal 880 may be interposed between the connection pad 810 and the upper pad 17 and may include, for example, a soldering material. The electronic device 800 may be electrically connected to the first to fourth semiconductor dies 100, 200, 300, and 400 through the substrate 1. The electronic device 800 may be, for example, a memory controller. Alternatively, the electronic device 800 may be a capacitor. The mold layer 500 may cover the electronic device 800. Unlike the illustrated structure, in an embodiment, the electronic device 800 may be attached to a bottom surface of the substrate 1.

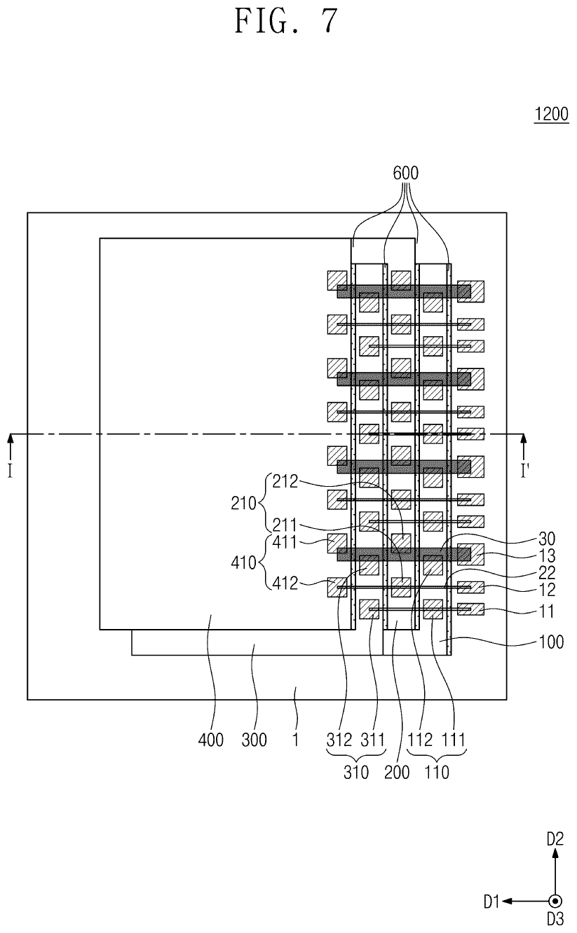

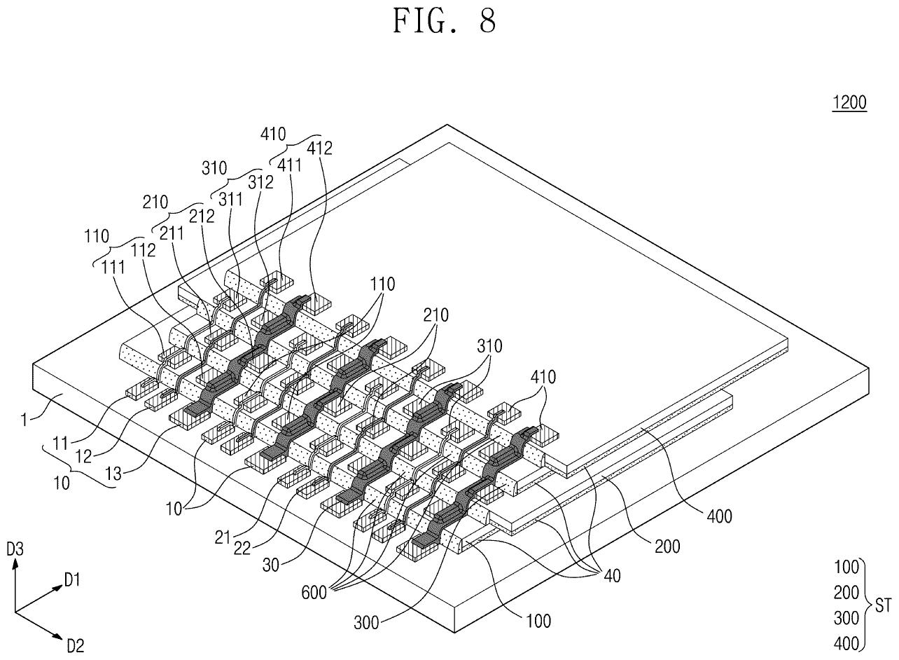

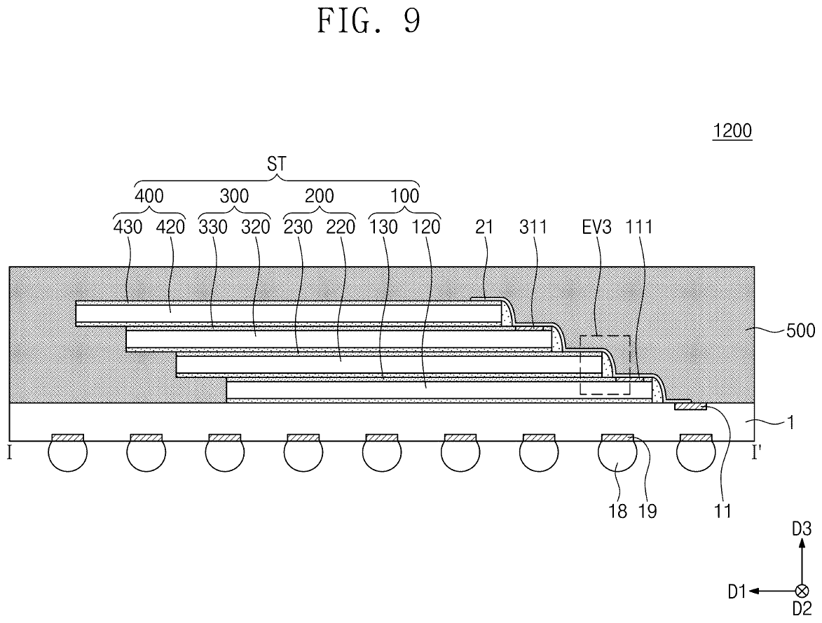

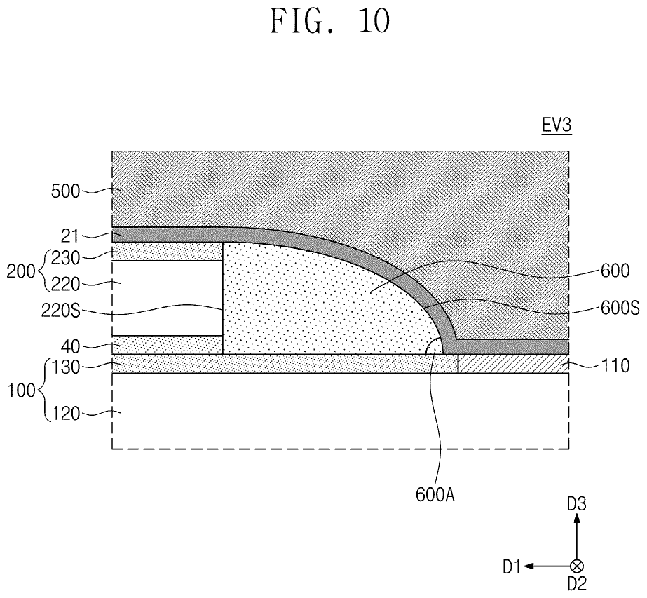

FIG. 7 is a plan view illustrating a semiconductor package according to an embodiment of the present disclosure. FIG. 8 is a perspective view of FIG. 7. FIG. 9 is a cross-sectional view taken along line I-I′ of FIG. 7. FIG. 10 is an enlarged view illustrating a portion ‘EV3’ of FIG. 9.

Referring to FIGS. 7, 8, 9, and 10, insulating patterns 600 may be respectively disposed on the side surfaces of the semiconductor dies 100, 200, 300, and 400. The insulating pattern 600 may include a polymer insulating material. The insulating pattern 600 may include an under-fill material or an organic material. For example, the insulating pattern 600 may include an epoxy resin. The insulating pattern 600 may serve as a slope relieving structure reducing the slope of the side surface of each of the semiconductor dies 100, 200, 300, and 400. The first, second, and third conductive patterns 21, 22, and 30 may be spaced apart from the side surfaces of the semiconductor dies with the insulating pattern 600 interposed therebetween. Each of the first, second, and third conductive patterns 21, 22, and 30 may be disposed on a side surface 600S of the insulating pattern 600 and may be in contact with the side surface 600S of the insulating pattern 600. An adhesion property of the first, second, and third conductive patterns 21, 22, and 30 to the insulating pattern 600 may be stronger than an adhesion property of the first, second, and third conductive patterns 21, 22, and 30 to the semiconductor substrate (e.g., 220). The insulating pattern 600 may be a line-shaped pattern extended in the second direction D2, when viewed in a plan view. In an embodiment, the insulating pattern 600 may be provided to have a plurality of separated patterns, which are locally formed to be in contact with or adjacent to the first, second, and third conductive patterns 21, 22, and 30. As shown in FIG. 10, a first angle 600A between the side surface 600S of the insulating pattern 600 and the top surface of the semiconductor die (e.g., 100) may be greater than about 0° and smaller than about 90°. For example, the first angle 600A may range from about 30° to about 60°, however, is not limited to this example. The width of the insulating pattern 600 in the first direction D1 may be greater than the height of the insulating pattern 600 in the third direction D3. That is, when viewed in a cross-sectional view, the insulating pattern 600 may have a shape similar to a right triangle with a base longer than its height. Although the side surfaces of the semiconductor dies 100, 200, 300, and 400 have a slope angle of about 90°, it may be possible to prevent the first, second, and third conductive patterns 21, 22, and 30 from being cut at a sharp slope region between the semiconductor dies, because the insulating pattern 600 having a gentle slope angle is additionally provided. For example, the insulating pattern 600 may be in contact with the side surface 220S of the second semiconductor substrate 220, the side surface of the second insulating layer 230, the side surface of the adhesive layer 40, and the top surface of the first insulating layer 130. In an embodiment, the slope of a side surface of the insulating pattern 600 may be less steep than the slope of a side surface of the second semiconductor die 200. In an embodiment, the insulating pattern 600 does not cover the pad (e.g., 110), and thus, the pad may be exposed.

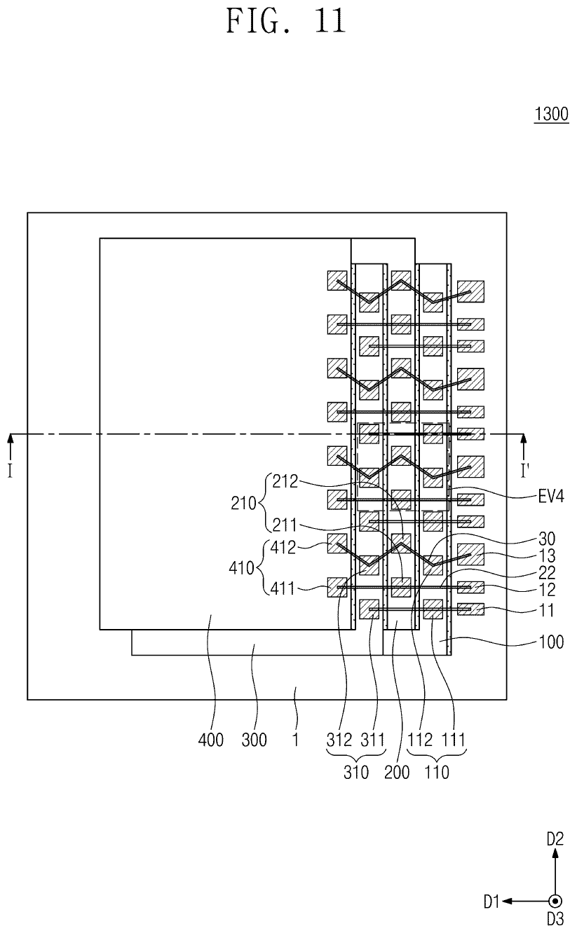

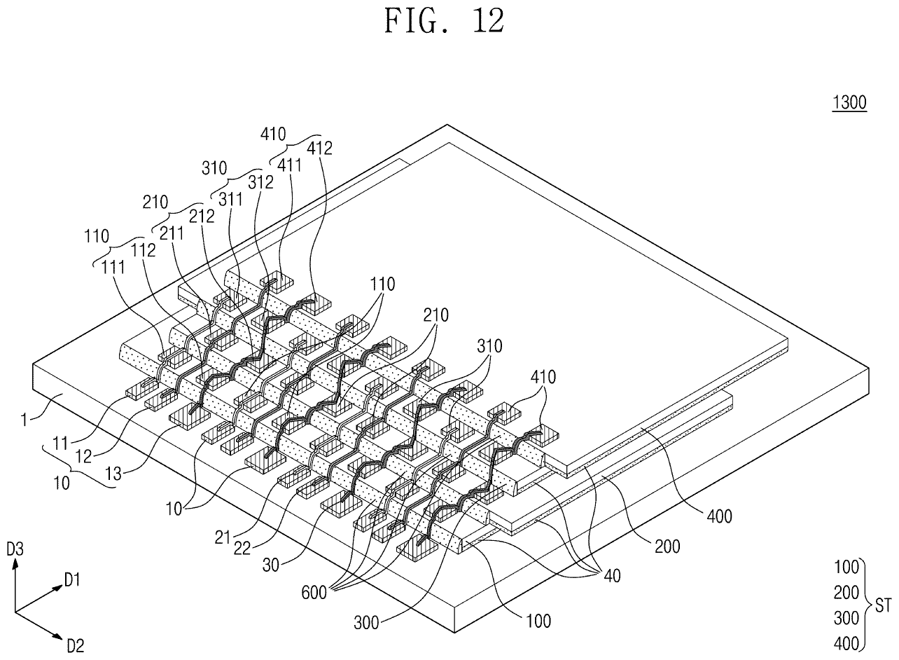

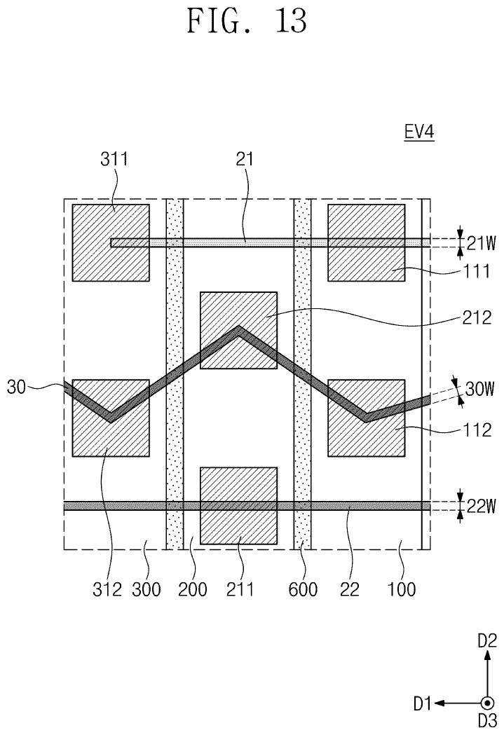

FIG. 11 is a plan view illustrating a semiconductor package according to an embodiment of the present disclosure. FIG. 12 is a perspective view of FIG. 11. FIG. 13 is an enlarged view illustrating a portion ‘EV4’ of FIG. 11. For convenience of explanation, a further description of elements and technical aspects previously described with reference to FIGS. 8 to 10 may be omitted.

Referring to FIGS. 11 to 13, when viewed in a plan view, the third conductive pattern 30 may be a line-shaped pattern, which is extended in a zigzag shape along the first direction D1. That is, the third conductive pattern 30 may have a plurality of bending portions, when viewed in a plan view. As shown in FIG. 13, the third width 30W of the third conductive pattern 30 may be about equal to the first width 21W of the first conductive pattern 21 or the second width 22W of the second conductive pattern 22.

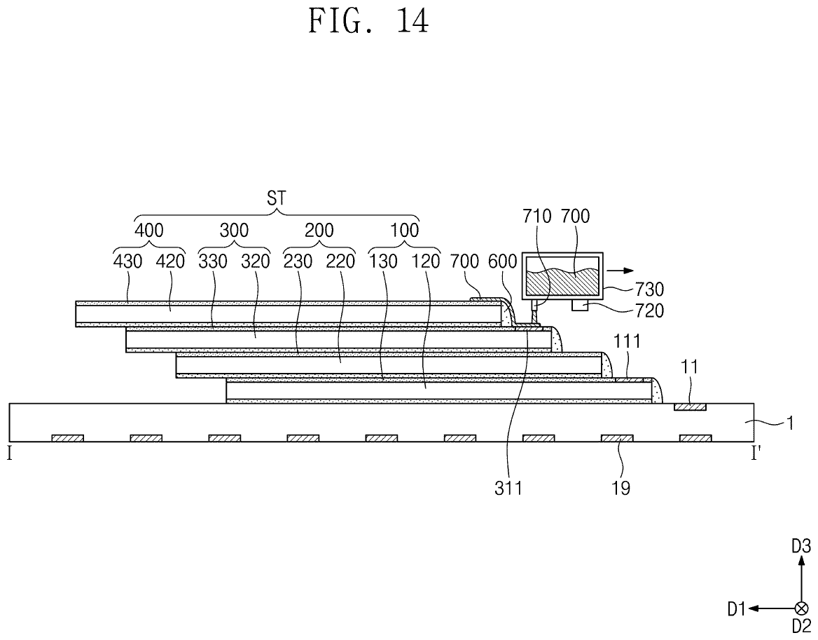

FIG. 14 is a cross-sectional view illustrating a method of fabricating a semiconductor package according to an embodiment of the present disclosure.

Referring to FIG. 14, the semiconductor die stack ST may be formed on the substrate 1. The formation of the semiconductor die stack ST may include sequentially stacking the first to fourth semiconductor dies 100, 200, 300, and 400 to be offset from each other. Next, the insulating pattern 600 may be formed by coating the side surface of each of the first to fourth semiconductor dies 100, 200, 300, and 400 with a polymer insulating material (e.g., an under-fill material). A container 730, in which a conductive material 700 is contained, may be prepared. The conductive material 700 may be a solid material in a powder state or a fluidic liquid material. The conductive material 700 may be ejected through a first nozzle 710. The conductive material 700 may be ejected to top and side surfaces of a semiconductor die and may be solidified to form the aforementioned conductive pattern. For example, the formation of the conductive pattern may include using an inkjet printing technique. For example, a silver nanoparticle ink may be printed to form a shape corresponding to the conductive pattern. Next, a sintering process may be performed, and in this case, silver particles in the printed ink may be combined to form the conductive pattern. The width of the conductive pattern may be determined by the diameter of the nozzle. For example, the first nozzle 710, which is connected to the container 730 and has a small diameter, may be used to form the first and second conductive patterns 21 and 22 having a small width. The third conductive pattern 30 having a large width may be formed through a second nozzle 720 having a larger diameter than the first nozzle 710. In an embodiment, the first, second, and third conductive patterns 21, 22, and 30 may be formed using the nozzle of the same diameter (e.g., see FIGS. 11, 12, and 13). The first, second, and third conductive patterns 21, 22, and 30 may be formed at the same time or different times.

Referring back to FIG. 3, the mold layer 500 may be formed after the formation of the first, second, and third conductive patterns 21, 22, and 30. The outer connection terminals 18 may be formed on the lower pads 19 of the substrate 1. As a result, the semiconductor package according to an embodiment of the present disclosure may be formed.

In a semiconductor package according to an embodiment of the present disclosure, by using a conductive pattern connecting semiconductor dies to each other, the electrical path may be shortened and the overall height of the package may be reduced. Since semiconductor dies with different signal channels are efficiently stacked in a single stack and are connected to each other, the area of the package may be reduced. In addition, a common conductive pattern may be used to effectively execute the voltage management in the semiconductor dies. As a result, signal transmission efficiency and reliability in the semiconductor package may be increased.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A semiconductor package, comprising:
a substrate;
a first semiconductor die disposed on the substrate;
a second semiconductor die disposed on the first semiconductor die;
a third semiconductor die disposed on the second semiconductor die;
a first conductive pattern; and
a second conductive pattern,
wherein the second semiconductor die is stacked on the first semiconductor die and is offset from the first semiconductor die in a first direction and a second direction, which are perpendicular to each other,
the third semiconductor die is stacked on the first and second semiconductor dies and is offset from the first and second semiconductor dies in the first direction,
the first semiconductor die comprises a first pad and a second pad, which are successively arranged in the second direction,
the second semiconductor die comprises a third pad and a fourth pad, which are successively arranged in the second direction,
the third semiconductor die comprises a fifth pad and a sixth pad, which are successively arranged in the second direction,
the first conductive pattern connects the first and fifth pads,
the second conductive pattern connects the second, fourth, and sixth pads, and
the first and second conductive patterns are spaced apart from the third pad.

2. The semiconductor package of claim 1, wherein each of the first, third, and fifth pads is a signal pad,
each of the second, fourth, and sixth pads is one of a power pad and a ground pad, and
the second, fourth, and sixth pads are pads of a same type.

3. The semiconductor package of claim 1, wherein the third semiconductor die is disposed at a same position as the first semiconductor die in the second direction.

4. The semiconductor package of claim 1, wherein the first and second pads are repeatedly arranged in the second direction at a first pitch, and
the second semiconductor die is spaced apart from the first semiconductor die in the second direction by a distance less than or about equal to half of the first pitch.

5. The semiconductor package of claim 1, wherein a thickness of the second conductive pattern is greater than a thickness of the first conductive pattern.

6. The semiconductor package of claim 1, wherein the first conductive pattern is in contact with a top surface of the second semiconductor die.

7. The semiconductor package of claim 1, wherein the first conductive pattern is in contact with a side surface of the second semiconductor die.

8. The semiconductor package of claim 1, wherein the first conductive pattern is in contact with a top surface of the second semiconductor die and is spaced apart from a side surface of the second semiconductor die.

9. The semiconductor package of claim 1, wherein the first and second conductive patterns have a straight-line shape extending in the first direction, when viewed in a plan view.

10. The semiconductor package of claim 1, wherein the first conductive pattern has a line shape extending in the first direction, when viewed in a plan view, and
the second conductive pattern has a zigzag shape extending along the first direction.

11. The semiconductor package of claim 1, further comprising:
an insulating pattern disposed on a side surface of the second semiconductor die,
wherein the first and second conductive patterns are in contact with the insulating pattern.

12. The semiconductor package of claim 11, wherein the insulating pattern comprises an epoxy resin.

13. The semiconductor package of claim 11, wherein a slope of a side surface of the insulating pattern is less steep than a slope of the side surface of the second semiconductor die.

14. The semiconductor package of claim 1, further comprising:
a fourth semiconductor die disposed on the third semiconductor die,
wherein the fourth semiconductor die comprises a seventh pad and an eighth pad, which are successively arranged in the second direction; and
a third conductive pattern connecting the third and seventh pads to each other,
wherein the third conductive pattern is disposed between the first and second conductive patterns, and
the second conductive pattern is in contact with the eighth pad.

15. The semiconductor package of claim 14, wherein the fourth semiconductor die is stacked on the third semiconductor die and is offset from the third semiconductor die in the first and second directions, and
the fourth semiconductor die is disposed at a same position as the second semiconductor die in the second direction.

16. A semiconductor package, comprising:
a substrate;
a first semiconductor die disposed on the substrate;
a second semiconductor die disposed on the first semiconductor die;
a first conductive pattern; and
a second conductive pattern,
wherein the second semiconductor die is stacked on the first semiconductor die and is offset from the first semiconductor die in a first direction and a second direction, which are perpendicular to each other,
the substrate comprises a first substrate pad and a second substrate pad, which are spaced apart from each other in the second direction,
the first semiconductor die comprises a first insulating layer and a first pad exposed from the first insulating layer,
the second semiconductor die comprises a second pad,
the first conductive pattern is disposed between the first substrate pad and the first pad,
the second conductive pattern is disposed between the second substrate pad and the second pad,
the second conductive pattern is spaced apart from the first conductive pattern, and
the second conductive pattern is in contact with a top surface of the first insulating layer.

17. The semiconductor package of claim 16, wherein the second conductive pattern is in contact with a side surface of the second semiconductor die.

18. The semiconductor package of claim 16, further comprising:
an insulating pattern disposed on a side surface of the second semiconductor die,
wherein the second conductive pattern is in contact with a side surface of the insulating pattern.

19. The semiconductor package of claim 18, wherein the insulating layer comprises an inorganic insulating material, and
the insulating pattern comprises a polymer material.

20. A semiconductor package, comprising:
a substrate;
a semiconductor die stack disposed on the substrate;
a mold layer covering a top surface and a side surface of the semiconductor die stack;
a first conductive pattern;
a second conductive pattern; and
a third conductive pattern,
wherein the semiconductor die stack comprises:
a first semiconductor die disposed on the substrate;
a second semiconductor die disposed on the first semiconductor die;
a third semiconductor die disposed on the second semiconductor die; and
a fourth semiconductor die disposed on the third semiconductor die,
wherein the second and fourth semiconductor dies are offset from the first semiconductor die in a first direction and a second direction,
the third semiconductor die is offset from the first semiconductor die in the first direction and is disposed at a same position in the second direction,
the fourth semiconductor die is offset from the second semiconductor die in the first direction and is disposed at a same position in the second direction,
the first semiconductor die comprises a first signal pad and a first voltage pad, which are spaced apart from each other in the second direction,
the second semiconductor die comprises a second signal pad and a second voltage pad, which are spaced apart from each other in the second direction,
the third semiconductor die comprises a third signal pad and a third voltage pad, which are spaced apart from each other in the second direction,
the fourth semiconductor die comprises a fourth signal pad and a fourth voltage pad, which are spaced apart from each other in the second direction,
the first conductive pattern connects the first and third signal pads,
the second conductive pattern connects the second and fourth signal pads, and
the third conductive pattern connects the first, second, third, and fourth voltage pads.
